(19) United States
(12) Patent Application Publication
(10) Pub. No.: US 2008/0202802 A1
(43) Pub. Date: Aug. 28, 2008

(54) Printed circuit board module having two printed circuit boards for mounting inline package elements and adhibit elements respectively

(75) Inventor: Jian-Hui Lu, Shenzhen (CN)

Correspondence Address: WEI TE CHUNG;FOXCONN INTERNATIONAL, INC., 1650 MEMOREX DRIVE, SANTA CLARA, CA, 95050, US

(73) Assignees: INNOCOM TECHNOLOGY (SHENZHEN) CO., LTD.; INNOLUX DISPLAY CORP.

(21) Appl. No.: 12/072,732

(22) Filed: Feb. 28, 2008

(30) Foreign Application Priority Data
Feb. 28, 2007 (CN) 200710073413.2

(51) Int. Cl. H05K 3/36; H05K 1/11

(52) U.S. Cl. 174/261; 29/830

(57) ABSTRACT

An exemplary printed circuit board (PCB) module (200) includes a first PCB (210); a second PCB electrically connected to the first PCB (230); a plurality of in-line package elements (220) provided on the first PCB and no surface-mounting elements provided thereon; and a plurality of surface-mounting elements (240) provided on the second PCB and no in-line package elements provided thereon.

### FIELD OF THE INVENTION

The present invention relates to printed circuit board (PCB) modules such as those used in LCDs (liquid crystal displays), and particularly to a PCB module having two PCBs for mounting in-line package elements and surface-mounting elements, respectively.

### GENERAL BACKGROUND

An LCD has the advantages of portability, low power consumption, and low radiation, and has been widely used in various portable information products such as notebooks, PDAs (personal digital assistants), video cameras and the like. Furthermore, the LCD is considered by many to have the potential to completely replace CRT (cathode ray tube) monitors and televisions.

Normally, an LCD includes an LCD panel, a backlight module configured for illuminating the LCD panel, and a PCB module configured for providing operation voltages respectively to the LCD panel and the backlight module. The PCB module receives image signals from an external circuit such as a computer, and transforms the image signals to the LCD panel.

FIG. 2 is an isometric view of a typical PCB module 100. FIG. 3 is an isometric inversed view of the PCB module 100. The PCB module 100 includes a rectangular PCB 110, a plurality of in-line package elements 120 such as dual in-line package elements or single in-line package elements, and a plurality of surface-mounting elements 130. The PCB 110 includes a first surface 114 and a second surface 116 opposite to the first surface 114. The PCB 110 further includes a plurality of pin through holes (not labeled), and a wiring layout 112. Each in-line package element 120 includes at least two pins (not labeled) for electrical connection.

The pins of the in-line package elements 120 are received and welded in the pin through holes such that the in-line package elements 120 are arranged on the first surface 114 of the PCB 110. The surface-mounting elements 130 are mounted on the second surface 116 of the PCB 110 by a surface mounted technology (SMT) such that the surface-mounting elements 130 are connected to the in-line package elements 120 via the wiring layout 112.

Normally, a method for manufacturing the PCB module 100 includes manufacturing the PCB 110 having the wiring layout 112 and the pin throngh holes formed in the PCB 110 according to a circuit design, welding the in-line package elements 120 on the first surface 114 of the PCB 110, and mounting the surface-mounting elements 130 on the second surface 116 of the PCB 110.

In the process for manufacturing the PCB module 100, in order to improve an efficiency of mounting the surface-mounting elements 130 with considering a size capacity of an SMT device for accommodating the PCB 110, the surface-mounting elements 130 are mounted on an integrated PCB. After the integrated PCB is placed into the SMT device and the surface-mounting elements 130 are mounted on a surface of the sintegrated PCB, the integrated PCB is cut off and separated to two PCBs 110. Because only two PCBs 110 are manufactured once, when a planty of PCBs 110 are manufactured by the above method, manufacturing time of mounting the surface-mounting elements 130 is long. Therefore the efficiency for manufacturing the PCB module 100 is low.

It is desired to provide a PCB module which can overcome the above-described deficiencies.

### SUMMARY

In one preferred embodiment, a PCB module includes a first PCB; a second PCB electrically connected to the first PCB; a plurality of in-line package elements provided on the first PCB and no surface-mounting elements provided thereon; and a plurality of surface-mounting elements provided on the second PCB and no in-line package provided thereon.

Other novel features and advantages will become more apparent from the following detailed description when taken in conjunction with the accompanying drawings.

### BRIEF DESCRIPTION OF THE DRAWINGS

FIG. 1 is an exploded, isometric view showing a PCB module according to an exemplary embodiment of the present invention.

FIG. 2 is an isometric view of a conventional PCB module.

FIG. 3 is an isometric, inversed view of the PCB module of FIG. 2.

### DETAILED DESCRIPTION OF PREFERRED EMBODIMENTS

Reference will now be made to the drawings to describe various embodiments of the present invention in detail.

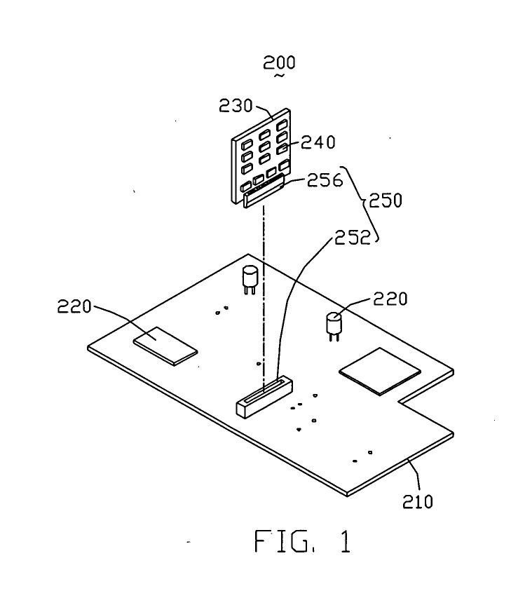

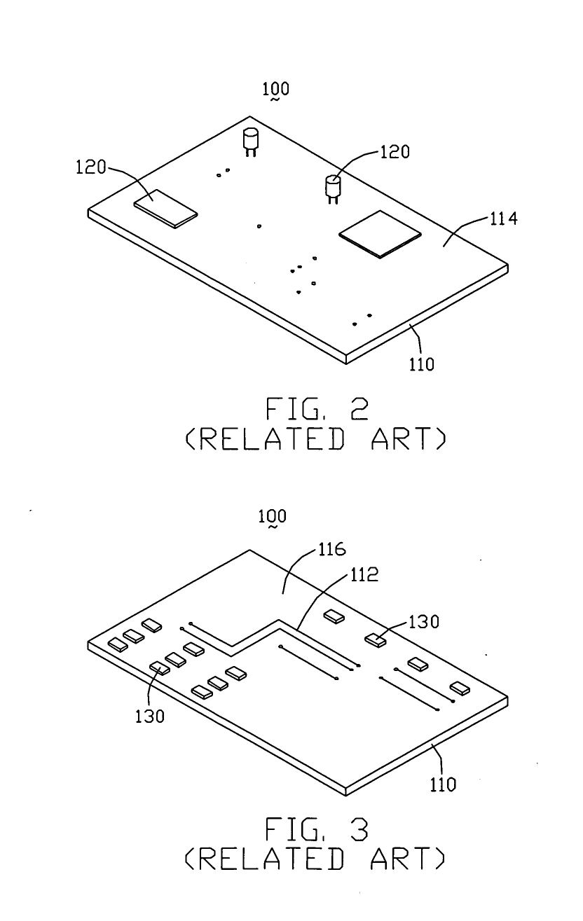

FIG. 1 is an exploded, isometric view of a PCB module 200 according to an exemplary embodiment of the present invention. The PCB module 200 includes a first PCB 210, a second PCB 230, a plurality of in-line package elements 220, a plurality of surface-mounting elements 240, and a connector 250. The in-line package elements 220 are welded in the first PCB 210. The surface-mounting elements 240 are mounted on the second PCB 230. The first and the second PCBs 210, 230 can be single-layer PCBs or double-layer PCBs. The in-line package elements 220 can be dual in-line package elements or single in-line package element.

The first PCB 210 includes a plurality of pin through holes (not labeled) and a first wiring layout (not shown) formed therein. The second PCB 230 includes a second wiring layout (not shown) formed thereat. Pins of the in-line package elements 220 are received and welded in the pin through holes of the first PCB 210 such that the in-line package elements 220 are electrically connected to one another through the first wiring layout. The surface-mounting elements 130 are mounted at a surface of the second PCB 230 by an SMT device such that the surface-mounting elements 240 are connected to one another through the second wiring layout.

The connector 250 is configured for electrically connecting the first PCB 210 and the second PCB 230. The connector 250 includes a socket 252 arranged on the first PCB 210 and a plug 256 arranged at an edge of the second PCB 230. The socket 252 includes a plurality of mating contact fingers (not shown) thererin connected to the first wiring layout. The plug 256 includes a plurality of connecting fingers (not shown) connected to the second wiring layout.

In a process of assembling the PCB module 200, the plug 256 is inserted into the socket 252. The socket 252 provides for electrical and mechanical connection of the plug 256 when the plug 256 is inserted into of the socket 252. Thus the in-line package elements 220 are electrically connected to the surface-mounting elements 230 via the first wiring layout, the connector 250, and the second wiring layout. A circuit diagram of the PCB module 200 is approximately equivalent to a typical PCB module.

A method for manufacturing the PCB module 200 includes the following steps:

In a first step, the first and second PCBs 210, 230 are provided. This includes manufacturing the first PCB 210 and the second PCB 230 for providing the first wiring layout and the pin throngh holes of the first PCB 210 and providing the second wiring layout of the second PCB 230.

In a second step, the in-line package elements 220 and the surface-mounting elements 230 are respectively mounted on the first PCB 210 and the second PCB 230. This includes inserting the pins of the in-line package elements 220 into the pin through holes of the first PCB 210, welding the in-line package elements 220 on a surface of the first PCB 210, providing an integrated PCB including a plurality of second PCBs 230 into an SMT device, mounting the surface-mounting elements 230 on a surface of the integrated PCB, and cutting off the integrated PCB to form the plurality of separate second PCBs 230.

In a third step, the first PCB 210 and the second PCB 230 are electrically connected. This includes inserting the plug 256 arranged on the second PCB 230 into the socket 252 arranged on the second PCB 230.

In an alternative embodiment of the present invention, a size of the integrated PCB can be determined according to two parameters. One parameter is a size of the second PCB 230, and the other parameter is a size capacity of the SMT device for accommodating the integrated PCB. For example, to a PCB module 200 used in a 17′LCD, the size of the second PCB 230 can be design to 3.3 cm*2.5 cm. Assume the size capacity of the SMT device is 290 cm*cm, an integrated PCB including thirty second PCBs 230 can be placed into the SMT device for mounting the surface-mounting elements 230 once. In a further alternative embodiment, the connector 250 can be replaced by a plurality of pin through holes in the first PCB 210 and a plurality of pins at the edge of the second PCB 230.

Because the PCB module 200 includes the first PCB 210, the second PCB 230 and the connector 250 for electrically connecting the first PCB 210 and the second PCB 230, a first process for welding the in-line package elements 220 and a second process for mounting the surface-mounting elements 240 can be performed simultaneously respectively. Thus time for manufacturing the PCB module 200 is reduced and the efficiency is improved. Furthermore, the sum size of the surface-mounting elements 240 is very small comparing with the size of the PCB module 200, thus an area of the second PCB 230 designed for mounting the surface-mounting elements 240 is also very small. Therefore, the integrated PCB including more second PCBs 230 can be provided into the SMT device for mounting the surface-mounting elements 240 at the same time. Thus the efficiency for mounting the surface-mounting elements 240 of the PCB module 200 is further improved.

It is to be further understood that even though numerous characteristics and advantages of preferred and exemplary embodiments have been set out in the foregoing description, together with details of the structures and functions of the embodiments, the disclosure is illustrative only; and that changes may be made in detail, especially in matters of shape, size, and arrangement of parts within the principles of the present invention to the full extent indicated by the broad general meaning of the terms in which the appended claims are expressed.

What is claimed is:

1. A printed circuit board (PCB) module, comprising:
a first PCB;
a second PCB electrically connected to the first PCB;
a plurality of in-line package elements provided on the first PCB and no surface-mounting elements provided thereon; and
a plurality of surface-mounting elements provided on the second PCB and no in-line package provided thereon.

2. The PCB module as claimed in claim 1, further comprising a connector configured for electrically connecting the first PCB and the second PCB.

3. The PCB module as claimed in claim 2, wherein the connector comprises a socket arranged on the first PCB and a plug arranged at an edge of the second PCB.

4. The PCB module as claimed in claim 3, wherein the socket comprises a plurality of mating contact fingers within the interior of socket, the plug comprising a plurality of connecting fingers.

5. The PCB module as claimed in claim 4, wherein the first PCB comprises a first wiring layout formed thereon, connected to the mating contact fingers of the socket.

6. The PCB module as claimed in claim 5, wherein the first PCB further comprises a plurality of pin through holes, pins of the in-line package elements being received and welded in the pin through holes such that the in-line package elements being electrically connected to one another through the first wiring layout.

7. The PCB module as claimed in claim 4, wherein the second PCB comprises a second wiring layout formed thereon, connected to the connecting fingers of the plug.

8. The PCB module as claimed in claim 7, wherein the surface-mounting elements are connected to one another through the second wiring layout.

9. The PCB module as claimed in claim 1, wherein the surface-mounting elements are mounted on a surface of the second PCB by a surface mounted technology (SMT) device.

10. The PCB module as claimed in claim 1, wherein the in-line package elements can be dual in-line package elements or single in-line package element.

11. A method for manufacturing the printed circuit board (PCB) module as claimed in claim 1, comprising:
providing the first second PCB and the second PCB;
mounting the in-line package elements on the first PCB and mounting the surface-mounting elements on the second PCB respectively; and
realizing the first PCB electrically connecting the second PCB.

12. The method as claimed in claim 11, wherein the process of providing the first PCB comprises forming the first wiring layout and the pin throngh holes in the first PCB.

13. The method as claimed in claim 12, wherein the process of mounting the in-line package elements comprises inserting pins of the in-line package elements into the pin through holes of the first PCB, and welding the in-line package elements at a surface of the first PCB.

14. The method as claimed in claim 11, wherein the process of providing the second PCB comprises forming a second wiring layout in the second PCB.

15. The method as claimed in claim 14, wherein the process of mounting the surface-mounting elements comprises providing an integrated PCB including a plurality of the second PCBs to an SMT device, mounting the surface-mounting elements at a surface of the integrated PCB, and cutting off the integrated PCB to separate the plurality of the second PCBs.

16. The method as claimed in claim 11, wherein the surface-mounting elements are mounted at a surface of the second PCB by surface mounted technology (SMT).

17. The method as claimed in claim 11, wherein the first PCB and the second PCB are connected by a connector.

18. A printed circuit board (PCB) module, comprising:
at least one in-line package elements;
at least one surface-mounting elements;
a first PCB for only mounting the in-line package element thereon; and
a second PCB for only mounting the surface-mounting element thereon;
wherein the first PCB is electrically connected to the second PCB.

19. The PCB module as claimed in claim 1, further comprising a connector configured for electrically connecting the first PCB and the second PCB.

20. The PCB module as claimed in claim 2, wherein the connector comprises a socket arranged on the first PCB and a plug arranged at an edge of the second PCB.
